(19) United States
(12) Patent Application Publication
(10) Pub. No.: US 2006/0185930 A1
(43) Pub. Date: Aug. 24, 2006

(54) Speaker assembly with a light-emitting function

(75) Inventor: Chih-Hao Shu, Taipei (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Compal Electronics, Inc.

(21) Appl. No.: 11/141,894

(22) Filed: Jun. 1, 2005

(30) Foreign Application Priority Data
Feb. 23, 2005 (TW) 94202882

(51) Int. Cl. H05K 5/00; A47B 81/06

(52) U.S. Cl. 181/148; 181/199

(57) ABSTRACT

A speaker assembly is made of a base unit, a light source, a ring and a cover. The speaker is built inside the base unit and its vibration surface is a reflection surface. Two more reflection surfaces are arranged around the base. Two light sources are respectively positioned on two reflection surfaces, by which the light can be emitted from light sources to be reflected uniformly. A ring, having a reflection surface, is disposed around the speaker so as to make it a unique, light-emitting object. The cover is mounted on the base to protect the speaker from damage.

### RELATED APPLICATIONS

The present application is based on, and claims priority from, Taiwan Application Serial Number 94202882, filed Feb. 23, 2005, the disclosure of which is hereby incorporated by reference herein in its entirety.

### BACKGROUND

1. Field of Invention

The present invention relates to a speaker assembly. More particularly, the present invention relates to a speaker assembly with a light-emitting function.

2. Description of Related Art

In the competitive market of multimedia equipment, most peripherals provide not only their basic, conventional functions, but also some additional functions to attract consumers.

Speakers are a kind of multimedia equipment, so speakers should provide some additional functions in addition to the basic functions to attract consumers, for the same reason.

A lighting function is a possible additional function for a speaker assembly. Referring to FIG. 1, Taiwan application no. 092215637 discloses a speaker assembly with a lighting function. The speaker assembly shown in FIG. 1 has a speaker 100 and lighting 102 means in front of the speaker 100 for projecting light outwards through a net cover 104. The uniformity of the light provided is, however, poor.

### SUMMARY

It is an object of the present invention to provide a speaker assembly with uniform light function so as to improve the additional value of speaker.

To achieve the above-mentioned object, the preferred embodiment of the present invention provides a speaker assembly with a light-emitting function. The speaker assembly includes a base unit, a plurality of light sources, a ring and a cover. A reflection surface is on the one side of the base unit, and a speaker having a vibration surface is built inside the base unit such that the reflection surface is engaged with the vibration surface. The reflection surface includes two side walls configured on the both transversal sides of the reflection surface. Each of the two sidewalls has a light source, and the light from this light source can be reflected by the reflection surface for providing uniform light. The ring having a reflective face on the surface thereof is disposed around the speaker for increasing the brightness of the vibration surface on the speaker. The cover covers the reflection surface for improving the uniformity of the light reflected by the reflection surface and the ring, and protecting the speaker from damage.

As embodied and broadly described herein, the invention provides a speaker assembly with a light function for providing uniform light. By using the reflection surface, the ring with reflective face, and the light sources around the reflection surface, the light provided by the speaker assembly of the preferred embodiment of the present invention is substantially uniform.

These and other features, aspects, and advantages of the present invention will become better understood with reference to the following description and appended claims.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 illustrates a conventional speaker assembly with lighting function;

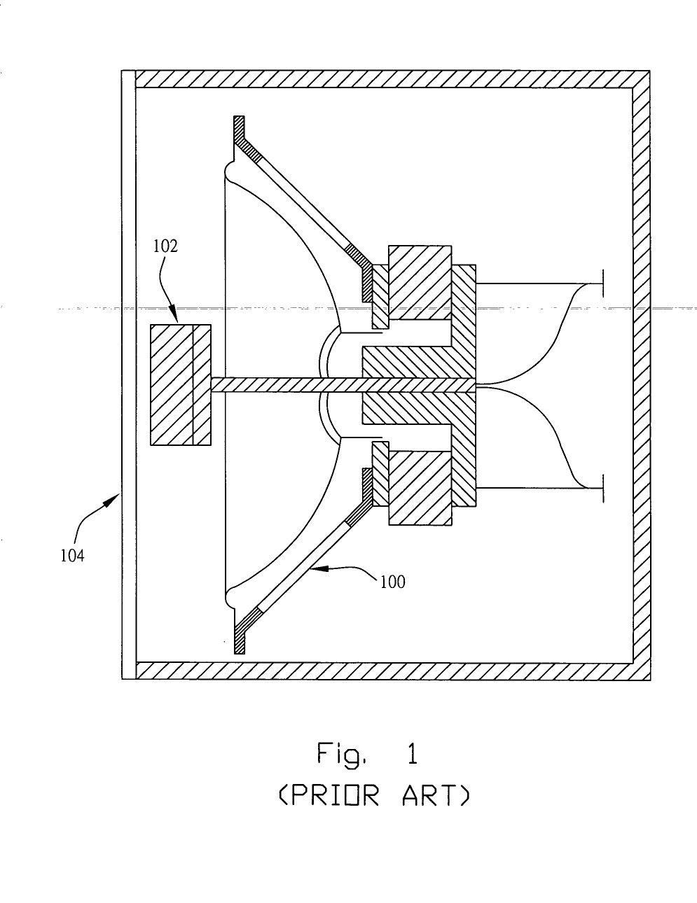

FIG. 2A is a front view showing the structure of a speaker assembly according to one preferred embodiment of this invention;

FIG. 2B is a schematic diagram showing the structure of a speaker assembly according to one preferred embodiment of this invention; and

FIG. 3 is an exploded view showing the parts of a speaker assembly according to one preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

A preferred embodiment of the present invention provides a speaker assembly having a reflection surface, a plurality of light sources around the reflection surface and a ring with a reflective face to provide uniform light.

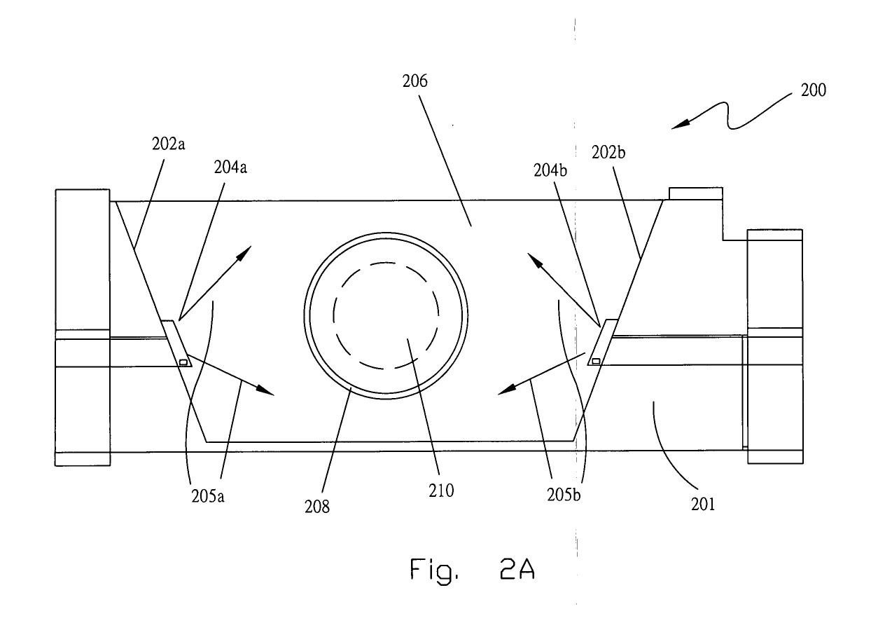

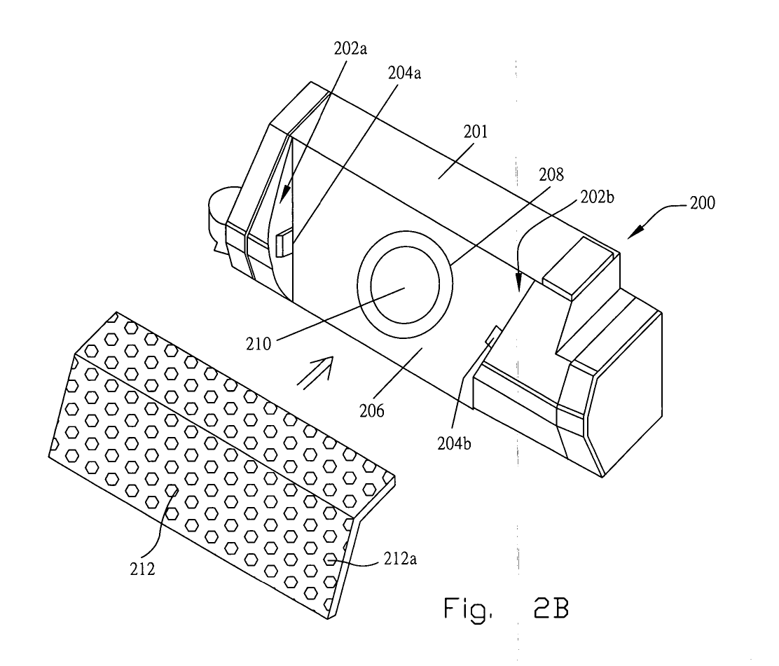

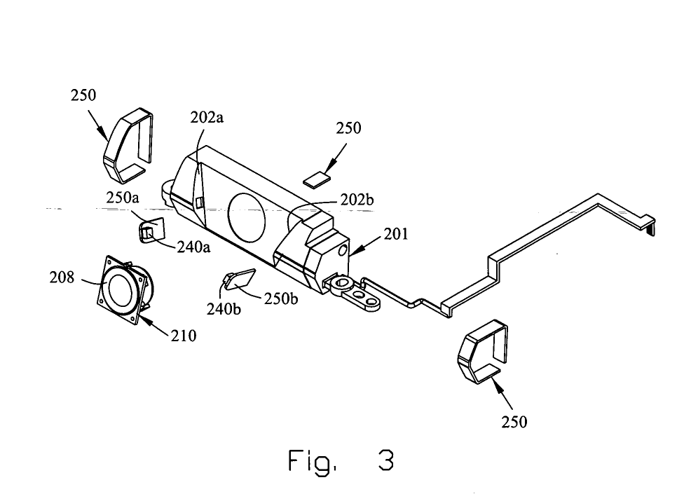

FIG. 2A is a front view showing the structure of a speaker assembly according to one preferred embodiment of this invention, FIG. 2B is a schematic diagram showing the structure of a speaker assembly according to one preferred embodiment of this invention, and FIG. 3 is an exploded view showing the parts of a speaker assembly according to one preferred embodiment of this invention. The speaker assembly 200 of the preferred embodiment of the present invention has a base unit 201 with a reflection surface 206 and a speaker 210 built inside the base unit 201. The base unit 201 can be equipped with an elastomer 250 on the top and both transverse sides of the base unit 201 for protecting the speaker assembly 200 from vibration. This elastomer 250 is an optional element so the scope of present invention should not be limited by the elastomer 250. The elastomer 250 can be a sponge. The reflection surface 206 of the base unit 210 is engaged with a vibration surface, which vibrates on the speaker 210 for projecting sound outward. The vibration surface of the speaker 210 is surrounded by a ring 208 with a reflective face 206.

The reflection surface 206 can have a layer of reflective paint. In one preferred embodiment, the layer of reflective paint is silver in color. Both transverse sides of the reflection surface 206 have a sidewall 202a, 202b, respectively, standing on the reflection surface 206. Two light sources 204a, 204b are equipped on the sidewalls 202a, 202b respectively. In one preferred embodiment, the light sources 204a, 204b are light-emitting diodes. The light 205a, 205b from these light sources 204a, 204b are reflected by the reflection surface 206. Therefore, the speaker assembly 200 of the preferred embodiment of the present invention can provide light with greater uniformity.

The ring 208 is positioned at the center of the reflection surface 206 for increasing the brightness on the center region of the reflection surface 206 so that the light provided by the speaker assembly 200 of the preferred embodiment of the present invention is uniform. In one preferred embodiment, the vibration surface is positioned at the center of the reflection surface 206 so the ring 208 surrounds the vibration surface, and the ring 208 has a reflective face, which can reflect the light on the surface of the ring 208. The reflective face can be made of a reflective material or a layer of reflective paint for reflecting the light, where the layer of paint is silver in color. If the speaker assembly 200 just includes the light sources 204a, 204b and the reflection surface 206 for light emission, the speaker assembly 200 would provide light with poor uniformity due to the poor brightness provided by the vibration surface of the speaker 210 because the vibration surface positioned at the center of the reflection surface 206 is usually dark in color. Thus, the vibration surface of the preferred embodiment of the present invention is surrounded by the ring 208 with the reflective face for increasing the brightness of the vibration surface so the speaker assembly 200 can provide uniform light.

When the speaker assembly 200 of the preferred embodiment of the present invention is installed in a notebook computer, LCD or digital television, a cover 212 (FIG. 2b) can cover the speaker 210 for increasing the uniformity of the light-emitting and protecting the speaker 210 from damage. The cover 212 can have uniform holes 212a so the light reflected by the reflection surface 206 can be radiated uniformly outward through the holes 212a.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A speaker assembly with a light-emitting function, the speaker assembly comprising:
a base unit, comprising a reflection surface which is comprising two side walls configured on the both transversal sides;
a speaker, arranged inside the base unit, comprising a vibration surface, wherein the vibration surface is on the same surface of the reflection surface;
a ring, positioned at a center of the reflection surface; and
a plurality of light sources, positioned on the two side walls, capable of providing the light reflected by the reflection surface and the ring, so that the speaker assembly with a light-emitting function.

2. The speaker assembly of claim 1, wherein the ring is disposed around the speaker.

3. The speaker assembly of claim 1, wherein the reflection surface comprises a layer of reflective paint.

4. The speaker assembly of claim 3, wherein the layer reflective paint is silver in color.

5. The speaker assembly of claim 1, further comprising a cover with uniform holes covering the reflection surface side of the base unit.

6. The speaker assembly of claim 1, wherein the light sources comprise a plurality of light emitting diodes.

7. The speaker assembly of claim 1, further comprising an elastomer located on a top and both transverse sides of the base unit.

8. The speaker assembly of claim 1, wherein the ring comprises a reflective material.

9. The speaker assembly of claim 1, wherein the ring comprises a layer of reflective paint.

10. The speaker assembly of claim 9, wherein the layer of reflective paint is silver in color.
